(19) United States
(12) Patent Application Publication
(10) Pub. No.: US 2017/0170213 A1
(43) Pub. Date: Jun. 15, 2017

(54) ARRAY SUBSTRATE, MANUFACTURING METHOD FOR ARRAY SUBSTRATE AND DISPLAY DEVICE

(71) Applicant: Shenzhen China Star Optoelectronics Technology Co., Ltd., Shenzhen, Guangdong (CN)

(72) Inventor: Wenhui LI, Shenzhen, Guangdong (CN)

(73) Assignee: Shenzhen China Star Optoelectronics Technology Co., Ltd., Shenzhen, Guangdong (CN)

(21) Appl. No.: 14/904,847

(22) PCT Filed: Jul. 31, 2015
(86) PCT No.: PCT/CN2015/085780

§ 371 Date: Jan. 19, 2016

(30) Foreign Application Priority Data
Jul. 16, 2015 (CN) 201510419425.0

(51) Int. Cl. H01L 27/12; H01L 29/51; H01L 29/49; H01L 29/45; H01L 29/786; H01L 29/24

(52) U.S. Cl. CPC H01L 27/1288; H01L 27/127; H01L 27/1225; H01L 29/7869; H01L 29/24; H01L 29/4908; H01L 29/45; H01L 29/51; H01L 29/518

(57) ABSTRACT

The present invention provides a manufacturing method for an array substrate including: forming a gate electrode; forming a gate insulation layer on the substrate and the first metal layer, and forming an oxide semiconductor layer on the gate insulation layer which is orthographically projected on the gate electrode; providing a photoresist layer on the oxide semiconductor layer; at two sides of the channel region of the oxide semiconductor layer are respectively a first oxide semiconductor layer and a second oxide semiconductor layer; performing a plasma treatment to the first and the second oxide semiconductor layer disposing with the photoresist layer; removing the photoresist layer; forming an etching stopper layer on the substrate; forming a source electrode and a drain electrode of the array substrate, wherein, the source electrode is contacted with the first oxide conductor layer and the drain electrode is contacted with the second oxide conductor layer.

### CROSS REFERENCE

This application claims the priority of Chinese Patent Application No. 201510419425.0, entitled “Array substrate, manufacturing method for array substrate and display device”, filed on Jul. 16, 2015, the disclosure of which is incorporated herein by reference in its entirety.

### FIELD OF THE INVENTION

The present invention relates to the manufacturing for an array substrate, and more particularly to an array substrate, a manufacturing method for array substrate and a display device.

### BACKGROUND OF THE INVENTION

The current oxide array substrate adopts oxide semiconductor as an active layer, which has features of large mobility, high on-state current, better switching characteristics, and better uniformity so that the oxide array substrate is suitable for an application requiring faster response and larger current such as a high-frequency, high-resolution, and large-size display device and an organic light emitting display device. The array substrate of the conventional art includes a gate line, a gate electrode, a semiconductor layer, a source and a drain electrode, an etching stopper layer, the insulating layer and the pixel electrode, etc. In the manufacturing process because of problems of precision and bias (such as exposing stage), when the source electrode and the drain electrode are formed on a second metal layer, the second metal layer and the etching stopper layer must have a certain of overlapping width in order to ensure that when the manufacturing process has a deviation, the second metal layer can completely cover the semiconductor layer such that a channel length formed by semiconductor layer is longer and the conductivity is poor, and the aperture ratio of the pixel is decreased.

### SUMMARY OF THE INVENTION

The present invention provides a manufacturing method for an array substrate to avoid that a channel length formed by semiconductor layer is longer and the conductivity is poor in order to ensure the aperture ratio of the array substrate.

The present invention provides a manufacturing method for an array substrate, comprising:

providing a substrate;

forming a first metal layer on the substrate, and through a patterning process to make the first metal layer to form a gate electrode;

forming a gate insulation layer on the substrate and the first metal layer, and the gate insulation layer covers a surface of the substrate and the gate electrode;

forming an oxide semiconductor layer on the gate insulation layer which is orthographically projected on the gate electrode, wherein a width of the oxide semiconductor layer and a width of the gate electrode are the same;

providing a photoresist layer on the oxide semiconductor layer, a width of the photoresist layer is less than the oxide semiconductor layer, a portion of the oxide semiconductor layer directly opposite to a projection of the photoresist layer is a channel region, and at two sides of the channel region of the oxide semiconductor layer are respectively a first oxide semiconductor layer and a second oxide semiconductor layer;

performing a plasma treatment to the first oxide semiconductor layer and the second oxide semiconductor layer disposing with the photoresist layer such that the first oxide semiconductor layer and the second oxide semiconductor layer which are uncovered by the projection of the photoresist layer are converted into a first oxide conductor layer and a second oxide conductor layer;

removing the photoresist layer;

forming an etching stopper layer on the substrate where the gate insulation layer, the channel region, the first oxide conductor layer and the second oxide conductor layer are formed;

forming a second metal layer on the substrate, patterning the second metal layer in order to form a source electrode and a drain electrode of the array substrate, wherein, the source electrode is contacted with the first oxide conductor layer and the drain electrode is contacted with the second oxide conductor layer.

Wherein, the plasma treatment injects nitrogen gas or ammonia gas into the first oxide semiconductor layer and the second oxide semiconductor layer.

Wherein, a material of the oxide semiconductor layer is indium gallium zinc oxide (IGZO), zinc oxide (ZnO), indium zinc oxide (InZnO) or zinc tin oxide (ZnSnO).

Wherein, a material of the etching stopper layer is silicon oxide.

Wherein, a material of the first metal layer is selected from one of copper, tungsten, chromium, aluminum and a combination of copper, tungsten, chromium, and aluminum, and a material of the second metal layer is selected from one of copper, tungsten, chromium, aluminum and a combination of copper, tungsten, chromium, and aluminum.

Wherein, the method further comprises steps of forming an insulation-protection layer on the substrate and the patterned second metal layer, and patterning the insulation and protection layer.

Wherein, the gate insulation layer and the insulation-protection layer are made of one of silicon oxide (SiOx), silicon nitride (SiNx) and silicon oxynitride (SiNxOy).

Wherein, the gate insulation layer and the insulation-protection layer are formed by a patterning process.

The present invention provides an array substrate, and the array substrate, comprising:

a substrate;

a gate electrode formed on the substrate;

a gate insulation layer covering the gate electrode;

a channel region located directly above gate electrode;

a first oxide semiconductor layer and a second oxide semiconductor layer, and the first oxide semiconductor layer and the second oxide semiconductor layer are respectively connected with two sides of the channel region, and are disposed with the channel region in a same plane, and the channel region, the first oxide semiconductor layer and the second oxide semiconductor layer are commonly covered on the gate electrode;

an etching stopper layer formed on the substrate, covering the gate insulation layer and the channel region; and

a source electrode and a drain electrode formed on the etching stopper layer, the source electrode and the drain electrode are located at two sides of the channel region, the source electrode covers and contacts the first oxide semiconductor layer, and the drain electrode covers and contacts the second oxide semiconductor layer.

The present invention also provides a display device, which includes the array substrate described above.

The manufacturing method of the array substrate forms an oxide semiconductor layer on the gate insulation layer, through disposing the photoresist layer to block a portion of the oxide semiconductor layer as a channel region, through a plasma treatment to convert two oxide semiconductor layers at two sides of the channel region to form a first oxide conductor layer and a second oxide conductor layer which have less oxygen content, and the first oxide conductor layer and the second oxide conductor layer are used to be contacted with the source electrode and the drain electrode. Accordingly, when a deviation is generated in the manufacturing process, the second metal layer can contact with the source electrode and the drain electrode, and an entire length of the channel region is reduced so as to reduce a size of the array substrate and increase the aperture ratio and the conductivity property.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a flowchart of a manufacturing method for an array substrate according to an embodiment of the present invention; and

FIG. 2 to FIG. 9 is a schematic cross-sectional view at every manufacturing process for the array substrate according to an embodiment of the present invention.

### DETAILED DESCRIPTION OF THE PREFERRED EMBODIMENT

The following content combines figures and embodiments for detail description of the present invention.

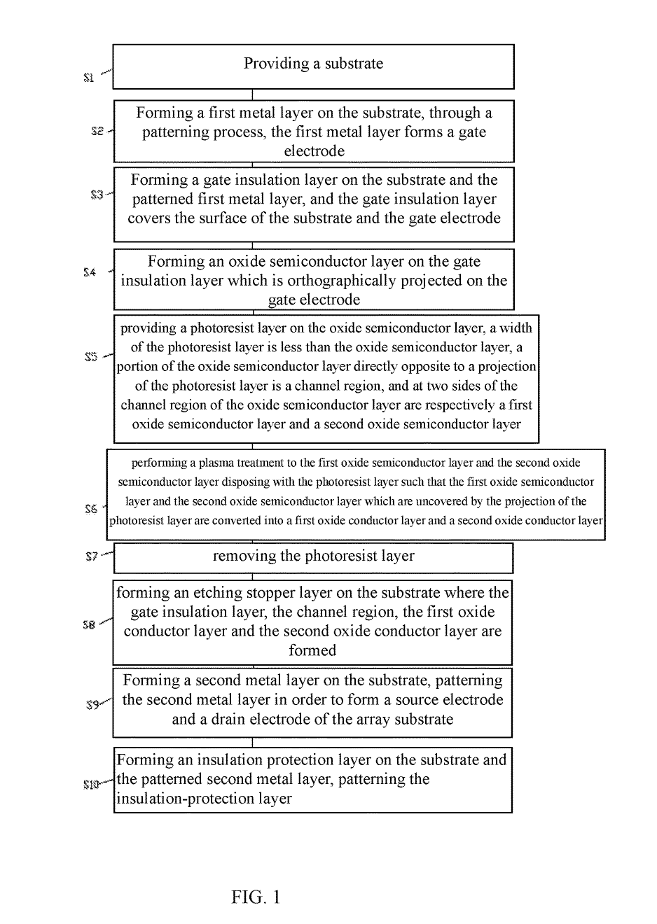

With reference to FIG. 1, and FIG. 1 is a flowchart of a manufacturing method for an array substrate according to an embodiment of the present invention. The array substrate belongs to an oxide semiconductor transistor. Before illustrating a specific manufacturing method, it can be understood that in the present invention, a patterning is a patterning process which can include a mask process or a mask and an etching process. At the same time, the patterning can also include printing, ink jet and other process for forming a predetermined pattern. The mask process means film forming, exposing, developing and so on and using photoresist, mask, and exposure machine. A corresponding patterning process can be selected according to the structure formed in the present invention.

The manufacturing method for an array substrate includes following steps:

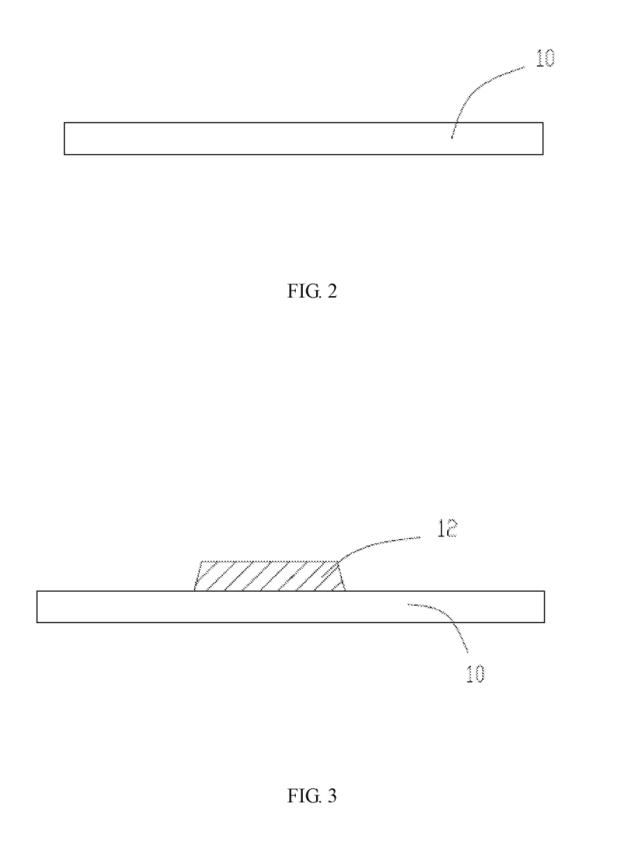

Step S1, providing a substrate 10. With combined reference to FIG. 2, in the present embodiment, the substrate 10 is a glass substrate. It can be understood that in another embodiment, the substrate 10 is not limited to the glass substrate.

With combined reference to FIG. 3, in a step S2, forming a first metal layer (not shown in the figure) on the substrate 10. Through a patterning process, the first metal layer forms a gate electrode 12. Specifically, forming the first metal layer on a surface of the substrate 10 as the gate electrode 12 of the array substrate 10. A material of the first metal layer is selected from one of copper, tungsten, chromium, aluminum and a combination of copper, tungsten, chromium, and aluminum. In the present embodiment, through the conventional art of photoresist coating, exposing ,developing, and so on to patterning the first metal layer in order to form the gate electrode 12.

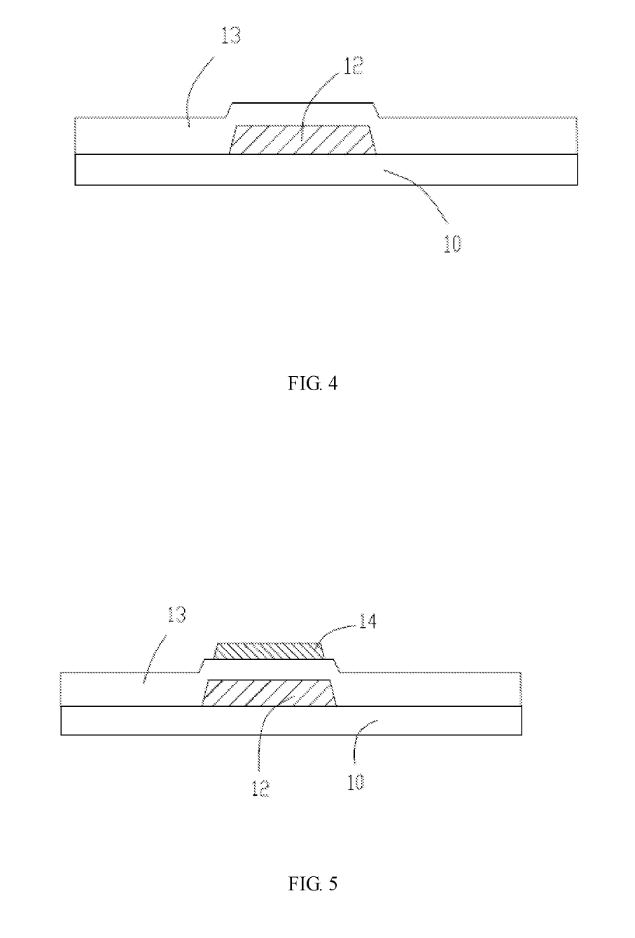

With reference to FIG. 4, in a step S3, forming a gate insulation layer 13 on the substrate 10 and the patterned first metal layer. The gate insulation layer 13 covers the surface of the substrate 10 and the gate electrode 12. Specifically, the gate insulation layer 130 is formed on the gate electrode 12 and a surface of the substrate 10 not covering by the first metal layer. The material of the gate insulation layer 13 is selected from one of silicon oxide, silicon nitride layer, silicon oxynitride layer and a combination of silicon oxide, silicon nitride layer, and silicon oxynitride layer.

With combined reference to FIG. 5, in a step S4, forming an oxide semiconductor layer 14 on the gate insulation layer 13 which is orthographically projected on the gate electrode 12. Wherein, a width L1 of the oxide semiconductor layer 14 and a width L2 of the gate electrode 12 are the same. The material of the oxide semiconductor layer 14 is indium gallium zinc oxide (IGZO), zinc oxide (ZnO), indium zinc oxide (InZnO) or zinc tin oxide (ZnSnO). Preferably, the oxide semiconductor layer 14 adopts indium gallium zinc oxide (IGZO) having oxygen content in the range of 0-10%.

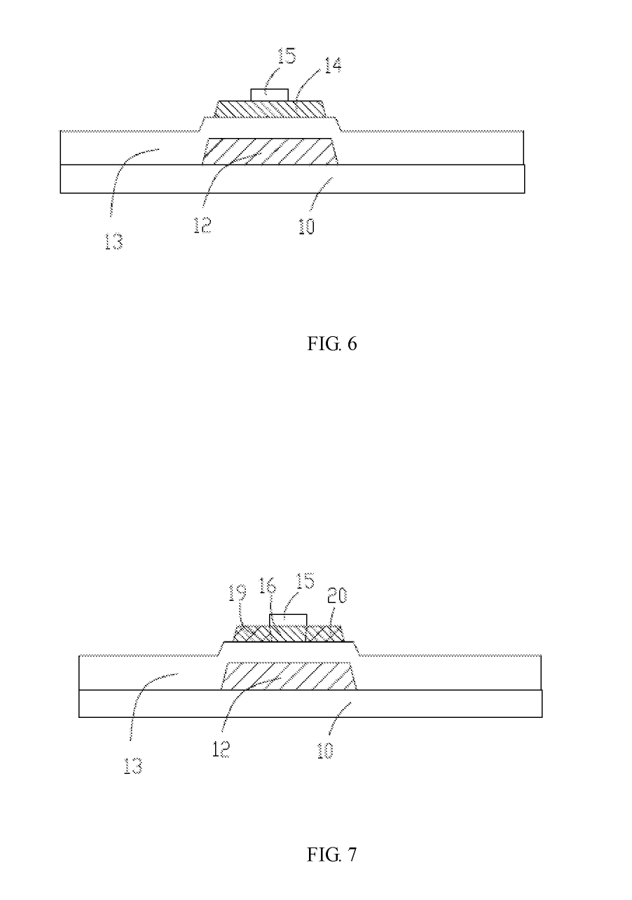

With combined reference to FIG. 6, in a step S5, a photoresist layer 15 is disposed on the oxide semiconductor layer 14. The photoresist layer 15 is orthographically projected on the oxide semiconductor layer 14, and a portion of the oxide semiconductor layer 14 directly opposite to a projection of the photoresist layer 15 is a channel region 16. At two sides of the channel region 16 of the oxide semiconductor layer 14 are respectively a first oxide semiconductor layer 141 and a second oxide semiconductor layer 142.

With combined reference to FIG. 7, in a step S6, performing a plasma treatment to the first oxide semiconductor layer 141 and the second oxide semiconductor layer 142 disposing with the photoresist layer 15 such that the first oxide semiconductor layer 141 and the second oxide semiconductor layer 142 which are uncovered by the projection of the photoresist layer 15 are converted into a first oxide conductor layer 17 and a second oxide conductor layer 18. The plasma treatment injects nitrogen gas or ammonia gas into the first oxide semiconductor layer 141 and the second oxide semiconductor layer 142 such that an oxygen content inside the first oxide semiconductor layer 141 and the second oxide semiconductor layer 142 are reduced so as to reduce the resistance.

In a step S7, removing the photoresist layer 15. The purpose is to reveal the channel region.

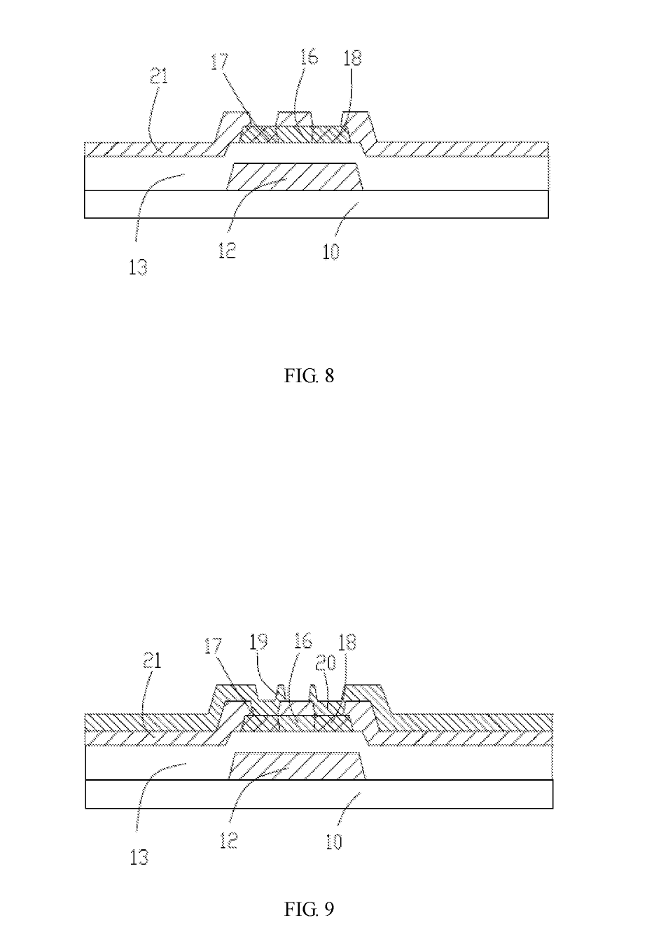

With combined reference to FIG. 8, in a step S8, forming an etching stopper layer 21 on the substrate where the gate insulation layer, the channel region, the first oxide conductor layer 19 and the second oxide conductor layer 20 are formed. A material of the etching stopper layer 21 is silicon oxide. The etching stopper layer 21 covers the channel region 16 and reveal most portion of the first oxide conductor layer 17 and the second oxide conductor layer 18.

With combined reference to FIG. 9, in a step S9, forming a second metal layer (not shown in the figure) on the substrate 10, patterning the second metal layer in order to form a source electrode 19 and a drain electrode 20 of the array substrate. Wherein, the source electrode 19 is contacted with the first oxide conductor layer 17 and the drain electrode 20 is contacted with the second oxide conductor layer 18. The channel region 16 is located between the source electrode 19 and the drain electrode 20.

Specifically, the second metal layer and the first oxide conductor layer 17 and the second oxide conductor layer 18 and the gate insulation layer 13 are stacked sequentially. Through the conventional patterning process to perform a patterning process to the second metal layer in order to form the source electrode 19 and the drain electrode 20 as shown in the figure. A material of the second metal layer is selected from one of copper, tungsten, chromium, aluminum and a combination of copper, tungsten, chromium, and aluminum. Wherein, the source electrode 19 is contacted with the first oxide conductor layer 17, and the drain electrode 20 is contacted with the second oxide conductor layer 18 in order to form a connected or disconnected channel between the source electrode 19 and the drain electrode 20 of the array substrate, which is equal to an ohmic contact layer. Accordingly, the source electrode 19 and the drain electrode 20 can form a well ohmic contact with the channel region 16 respectively through the conductor layers below, which having a low resistance value, and realize a good conductivity property from the source electrode 19 and the drain electrode 20.

In the present embodiment, the material of the second metal layer is generally a metal material. However, the present invention is not limited. In another embodiment, the material of the second metal layer can use other conductive material such as alloy, nitride of a metal material, nitrogen oxide of a metal material or a stacked layer including a metal material and another conductive material.

In a step S10, forming an insulation-protection layer on the substrate 10 and the patterned second metal layer (source electrode 19 and drain electrode 20), patterning the insulation-protection layer. The gate insulation layer 13 and the insulation-protection layer are made of one of silicon oxide (SiOx), silicon nitride (SiNx) and silicon oxynitride (SiNxOy). To this step, the array substrate of the present embodiment is finished.

Furthermore, the gate insulation layer 13 and the insulation-protection layer are made of one of silicon oxide (SiOx), silicon nitride (SiNx) and silicon oxynitride (SiNxOy). In the present embodiment, the gate insulation layer and the etching stopper layer are formed through patterning process.

The manufacturing method of the array substrate forms an oxide semiconductor layer 14 on the gate insulation layer 13, through disposing the photoresist layer 15 to block a portion of the oxide semiconductor layer 14 as a channel region 16, through a plasma treatment to convert two oxide semiconductor layers 14 at two sides of the channel region 16 to form a first oxide conductor layer 17 and a second oxide conductor layer 18 which have less oxygen content, and the first oxide conductor layer 17 and the second oxide conductor layer 18 are used to be contacted with the source electrode 19 and the drain electrode 20. Accordingly, when a deviation is generated in the manufacturing process, the second metal layer can contact with the source electrode 19 and the drain electrode 20, and an entire length of the channel region 16 is reduced so as to reduce a size of the array substrate and increase the aperture ratio and the conductivity property.

According to the above manufacturing method for the array substrate, the present invention also relates to an array substrate including a substrate; a gate electrode formed on the substrate; a gate insulation layer covering the gate electrode; a channel region located directly above gate electrode; a first oxide semiconductor layer and a second oxide semiconductor layer, and the first oxide semiconductor layer and the second oxide semiconductor layer are respectively connected with two sides of the channel region, and are disposed with the channel region in a same plane, and the channel region, the first oxide semiconductor layer and the second oxide semiconductor layer are commonly covered on the gate electrode; an etching stopper layer formed on the substrate, covering the gate insulation layer and the channel region; and a source electrode and a drain electrode formed on the etching stopper layer, the source electrode and the drain electrode are located at two sides of the channel region, the source electrode covers and contacts the first oxide semiconductor layer, and the drain electrode covers and contacts the second oxide semiconductor layer.

The present invention also includes a display device including the above array substrate, the display device that can be formed through the manufacturing method for the array substrate can be: LCD panel, LCD TV, LCD monitors, OLED panels, OLED TV, electronic paper, digital photo frames, mobile phones, and so on.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A manufacturing method for an array substrate, comprising:
providing a substrate;
forming a first metal layer on the substrate, and through a patterning process to make the first metal layer to form a gate electrode;
forming a gate insulation layer on the substrate and the first metal layer, and the gate insulation layer covers a surface of the substrate and the gate electrode;
forming an oxide semiconductor layer on the gate insulation layer which is orthographically projected on the gate electrode, wherein a width of the oxide semiconductor layer and a width of the gate electrode are the same;
providing a photoresist layer on the oxide semiconductor layer, a width of the photoresist layer is less than the oxide semiconductor layer, a portion of the oxide semiconductor layer directly opposite to a projection of the photoresist layer is a channel region, and at two sides of the channel region of the oxide semiconductor layer are respectively a first oxide semiconductor layer and a second oxide semiconductor layer;
performing a plasma treatment to the first oxide semiconductor layer and the second oxide semiconductor layer disposing with the photoresist layer such that the first oxide semiconductor layer and the second oxide semiconductor layer which are uncovered by the projection of the photoresist layer are converted into a first oxide conductor layer and a second oxide conductor layer;
removing the photoresist layer;
forming an etching stopper layer on the substrate where the gate insulation layer, the channel region, the first oxide conductor layer and the second oxide conductor layer are formed; and
forming a second metal layer on the substrate, patterning the second metal layer in order to form a source electrode and a drain electrode of the array substrate, wherein, the source electrode is contacted with the first oxide conductor layer and the drain electrode is contacted with the second oxide conductor layer.

2. The manufacturing method for an array substrate according to claim 1, wherein, the plasma treatment injects nitrogen gas or ammonia gas into the first oxide semiconductor layer and the second oxide semiconductor layer.

3. The manufacturing method for an array substrate according to claim 2, wherein, a material of the oxide semiconductor layer is indium gallium zinc oxide (IGZO), zinc oxide (ZnO), indium zinc oxide (InZnO) or zinc tin oxide (ZnSnO).

4. The manufacturing method for an array substrate according to claim 1, wherein, a material of the etching stopper layer is silicon oxide.

5. The manufacturing method for an array substrate according to claim 1, wherein, a material of the first metal layer is selected from one of copper, tungsten, chromium, aluminum and a combination of copper, tungsten, chromium, and aluminum, and a material of the second metal layer is selected from one of copper, tungsten, chromium, aluminum and a combination of copper, tungsten, chromium, and aluminum.

6. The manufacturing method for an array substrate according to claim 1, wherein, the method further comprises steps of forming an insulation-protection layer on the substrate and the patterned second metal layer, and patterning the insulation and protection layer.

7. The manufacturing method for an array substrate according to claim 6, wherein, the gate insulation layer and the insulation-protection layer are made of one of silicon oxide (SiOx), silicon nitride (SiNx) and silicon oxynitride (SiNxOy).

8. The manufacturing method for an array substrate according to claim 1, wherein, the gate insulation layer and the insulation-protection layer are formed by a patterning process.

9. An array substrate, comprising:
a substrate;
a gate electrode formed on the substrate;
a gate insulation layer covering the gate electrode;
a channel region located directly above gate electrode;
a first oxide semiconductor layer and a second oxide semiconductor layer, and the first oxide semiconductor layer and the second oxide semiconductor layer are respectively connected with two sides of the channel region, and are disposed with the channel region in a same plane, and the channel region, the first oxide semiconductor layer and the second oxide semiconductor layer are commonly covered on the gate electrode;
an etching stopper layer formed on the substrate, covering the gate insulation layer and the channel region; and
a source electrode and a drain electrode formed on the etching stopper layer, the source electrode and the drain electrode are located at two sides of the channel region, the source electrode covers and contacts the first oxide semiconductor layer, and the drain electrode covers and contacts the second oxide semiconductor layer.

10. A display device including an array substrate as claimed in claim 9.
